(19) United States
(12) Patent Application Publication
(10) Pub. No.: US 2026/0359008 A1
(43) Pub. Date: Nov. 12, 2026

(54) METHODS AND APPARATUS FOR NEURAL NETWORK INFERENCE ACCELERATION

(71) Applicant: Texas Instruments Incorporated, Dallas, TX (US)

(72) Inventors: Kunal Ranjan Patel, Kuchinda (IN); Manu Mathew, Bengaluru (IN); Kunal Sah, Bengaluru (IN); Kaviraj Sankar, Chennai (IN); Pramod Kumar Swami, Bengaluru (IN)

(21) Appl. No.: 19/664,532

(22) Filed: Apr. 30, 2026

(30) Foreign Application Priority Data
May 8, 2025 (IN) 202541044512

(51) Int. Cl. G06F 7/523; G06F 1/03; G06F 5/01; G06F 7/50; H03M 7/24

(52) U.S. Cl. CPC G06F 7/523; G06F 1/03; G06F 5/01; G06F 7/50; H03M 7/24

(57) ABSTRACT

An example apparatus includes methods and apparatus for neural network inference acceleration. An example device includes a memory configurable to store a lookup table and a processing circuit coupled to the memory and configurable to: determine a first coefficient and a second coefficient stored in the lookup table at an index corresponding to a first portion of an input value; multiply the first coefficient by a second portion of the input value to determine a scaled contribution term; and add the scaled contribution term and the second coefficient to determine a resulting value.

### CROSS-REFERENCE TO RELATED APPLICATION

This patent application claims the benefit of and priority to Indian Provisional Patent Application No. 202541044512 filed May 8, 2025, which is hereby incorporated herein by reference in its entirety.

### TECHNICAL FIELD

This description relates generally to computing systems and, more particularly, to methods and apparatus for neural network inference acceleration.

### BACKGROUND

Neural networks are increasingly deployed in embedded and real-time systems across a wide range of applications, including automotive perception, robotics, object detection and classification, facial recognition, and path planning. In such applications, neural network inference is executed directly within firmware on resource-constrained devices, where power consumption, memory footprint, and computational throughput are critical design constraints. A neural network is composed of successive layers of operations. Many of these layers, such as matrix multiplication and convolution, operate on vectors and matrices and can be efficiently accelerated by dedicated hardware such as digital signal processors and matrix multiply accelerators. For simple arithmetic operations, integer representations may be substituted for floating-point values, and multiplication and division operations may be restructured to reduce computational cost.

In addition to matrix and vector operations, neural networks include layers that apply unary functions to individual input values. Such functions include, for example, sigmoid, exponential (exp), sine (sin), and related nonlinear activation functions. These functions operate on floating-point inputs and cannot be expressed exactly as linear or low-degree polynomial equations, making them ill-suited to the integer and shift-based optimizations applicable to linear operations. Because direct floating-point evaluation of nonlinear unary functions is computationally expensive and power-intensive, particularly on low-power embedded devices, various approximation techniques have been developed to reduce the cost of evaluating these functions at inference time. Known approximation approaches include Taylor series expansion and direct lookup table methods.

### SUMMARY

For neural network inference acceleration, an example device includes a memory configurable to store a lookup table. The device includes a processing circuit coupled to the memory and configurable to: determine a first coefficient and a second coefficient stored in the lookup table at an index corresponding to a first portion of an input value, multiply the first coefficient by a second portion of the input value to determine a scaled contribution term, and add the scaled contribution term and the second coefficient to determine a resulting value. Other examples are described.

For neural network inference acceleration, an example non-transitory computer readable medium including instructions configurable to cause a processor to perform operations. The operations include determine a first coefficient and a second coefficient stored in a lookup table at an index corresponding to a first portion of an input value. The operations include multiply the first coefficient by a second portion of the input value to determine a scaled contribution term. The operations include add the scaled contribution term and the second coefficient to determine a resulting value. Other examples are described.

For neural network inference acceleration, an example method includes determining a first coefficient and a second coefficient stored in a lookup table at an index corresponding to a first portion of an input value. The method includes multiplying the first coefficient by a second portion of the input value to determine a scaled contribution term. The method includes adding the scaled contribution term and the second coefficient to determine a resulting value. Other examples are described.

### BRIEF DESCRIPTION OF THE DRAWINGS

FIG. 1 is a block diagram of an example environment in which an example function approximation system operates to approximate nonlinear unary functions during neural network inference.

FIG. 2 is a block diagram illustrating an example process of computing a table index from an input value and retrieving a corresponding output value from a lookup table.

FIG. 3 is a graph illustrating an example linear interpolation of the exponential function exp (x) within a bin.

FIG. 4 is a flowchart representative of example machine-readable instructions or example operations for generating and utilizing a lookup table for inference.

FIG. 5 is a flowchart representative of example machine-readable instructions or example operations for iterative lookup table finetuning.

FIG. 6 is a graph illustrating a relationship between approximation error in a bin and a coefficient delta value.

FIG. 7 is a flowchart illustrating example machine-readable instructions for performing function approximation using lookup-based linear interpolation.

FIG. 8 is a flowchart illustrating example machine-readable instructions for performing function approximation using lookup-based quadratic interpolation.

FIG. 9 is a table comparing a maximum absolute approximation error of example linear and quadratic interpolation methods.

FIG. 10 is a diagram illustrating an example quantization operation.

FIG. 11 is a diagram illustrating example quantization parameter relationships.

FIG. 12 is a block diagram of an example processing system including programmable circuitry structured to execute, instantiate, or perform the example machine-readable instructions or perform the example operations of FIGS. 4, 5, 7, and/or 8 to implement the function approximation apparatus.

FIG. 13 is a block diagram of another example processing system including programmable circuitry structured to execute, instantiate, or perform the example machine-readable instructions or perform the example operations of FIGS. 4, 5, 7, and/or 8 to implement the function approximation apparatus.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Some existing systems for evaluating nonlinear unary functions suffer from limitations in accuracy, memory efficiency, or computational overhead that make them unsuitable for deployment in resource-constrained embedded inference systems. Accordingly, there exists a need for improved methods and apparatus for approximating nonlinear unary functions with high precision and low computational cost.

US Patent Application Publication Number 20260057226 describes a technique for quantizing machine learning models, particularly transformer networks, by clipping outlier values from observed activations and weights of a floating-point model based on calibration data, using metrics like standard deviation and mean to determine clipping thresholds. The clipped values are then used to compute quantization factors such as scale and offset that convert the model from floating-point to fixed-point precision for deployment on resource-constrained devices, resulting in improved accuracy and reduced error compared to quantization approaches that do not remove outliers. US Patent Application Publication Number 20260057226 is hereby incorporated herein in its entirety.

Disclosed herein are methods and apparatus for high-precision, low-power approximation of nonlinear unary functions using pre-computed, quantized polynomial interpolation coefficients stored in a lookup table. Prior to inference, interpolation coefficients for a target function are computed over a set of input bins using a pseudo-inverse fitting method that accounts for all data points within each bin, rather than only the endpoints. During coefficient computation, input values within each bin are normalized to preserve the numerical precision of the resulting coefficients. In some examples, the resulting coefficients are quantized using power-of-two scales, which enables scale adjustments during inference to be performed using bit-shift operations in place of multiplication or division, further reducing computational cost. The quantized coefficients may be further refined through an iterative finetuning process in which small delta values are applied to each bin's coefficients and evaluated across all candidate combinations, with the combination yielding the minimum approximation error retained. The finalized lookup table may be stored in on-chip memory prior to the start of inference.

The example lookup table is structured such that each entry stores multiple quantized interpolation coefficients packed into a 32-bit word. For linear interpolation according to an example, each entry stores a 16-bit slope coefficient b and a 16-bit intercept coefficient c. For quadratic interpolation according to an example, each entry stores an 8-bit quadratic coefficient a, an 8-bit linear coefficient b, and a 16-bit constant coefficient c. The differing bit widths of the coefficients reflect their differing quantization scales, each of which is selected to be a power of two to facilitate shift-based scale adjustment during inference.

Example differing bit widths assigned to three quadratic coefficients reflect the differing precision requirements of each term in the interpolation expression. The intercept coefficient c represents the dominant contribution to the output value for inputs near the lower boundary of each bin and must accurately represent the quantized function value at that point. Accordingly, c is assigned 16 bits to preserve sufficient precision across the full output range of the target function. The linear coefficient b is multiplied by the 8-bit fractional input, which takes values in the range of 0 to 255, and the resulting product is therefore bounded in magnitude relative to the intercept. Assigning 8 bits to b provides sufficient precision for this term given its bounded contribution. Similarly, the quadratic coefficient a is multiplied by the square of the 8-bit fractional input, which is an even smaller quantity for small fractional values, and 8 bits is sufficient to represent the quadratic contribution accurately within each bin. This asymmetric allocation allows all three coefficients to be packed into a single 32-bit lookup table entry while preserving the precision required for each term's contribution to the interpolated result.

During example inference, a 16-bit input value is divided into an 8-bit index and an 8-bit fractional component. The index is used to retrieve the pre-computed interpolation coefficients for the corresponding bin from the lookup table. The fractional component is then used as the interpolation variable in either a linear or quadratic polynomial evaluation, in which the individual terms are adjusted to account for the normalization applied during coefficient computation and scaled to a common representation using bit-shift operations before being summed. The most significant 16 bits of the result may be retained as the approximated output. Because all coefficient estimation is performed prior to inference and the runtime evaluation path consists entirely of integer arithmetic and bit shifts, the disclosed method requires no floating-point operations and no runtime coefficient estimation during inference.

The disclosed methods and apparatus may achieve substantial reductions in approximation error relative to prior lookup table approaches across a broad range of nonlinear unary functions, including sigmoid, exponential, logarithm, trigonometric, and hyperbolic functions, as well as activation functions commonly used in neural network inference such as sigmoid linear unit (SiLU), exponential linear unit (ELU), Gaussian error linear unit (GELU), and Mish. The approach is particularly well suited for deployment on embedded processors equipped with digital signal processors and matrix multiply accelerators, where minimizing runtime arithmetic complexity and on-chip memory consumption are primary design objectives. The techniques of this disclosure may achieve better accuracy, as compared to using a smaller lookup table, and consume less chip area, as compared to using a larger lookup table.

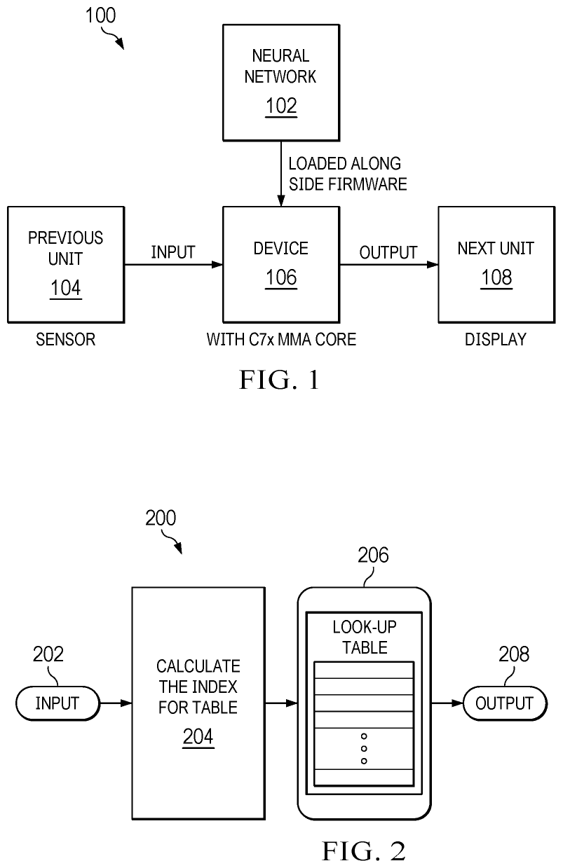

FIG. 1 illustrates an example environment 100 in which disclosed function approximation methods and apparatus may be implemented. In the illustrated example, the example environment 100 includes a neural network 102, a previous unit 104, a device 106, and a next unit 108. Although FIG. 1 depicts the example environment 100 as including neural network 102, the techniques of this disclosure may be used in computational systems without neural networks.

The example neural network 102 represents a trained inference model that is loaded alongside firmware onto the device 106. The neural network 102 includes a plurality of layers, among which are one or more unary activation function layers that apply nonlinear functions, such as sigmoid, exponential, or sine, to individual input values. It is the evaluation of these nonlinear unary function layers that the disclosed methods and apparatus are directed to accelerating.

The example previous unit 104 represents a unit earlier in a processing pipeline that supplies input data to the device 106. In the illustrated example, the previous unit 104 is associated with a sensor, such as, for example, a camera or other data acquisition device that generates the input data on which the neural network 102 performs inference.

The example device 106 represents a resource-constrained embedded processor on which the neural network 102 is deployed and executed. In the illustrated example, the device 106 includes a digital signal processor (DSP) (e.g., a C7x DSP) with a matrix multiply accelerator (MMA) core, which serves as the primary execution resource for the function approximation operations described herein. The device 106 receives input data from the previous unit 104, executes the neural network 102 including the disclosed lookup table-based function approximation operations for evaluating nonlinear unary function layers, and supplies the resulting output to the next unit 108.

The example next unit 108 represents a unit later in the processing pipeline that receives and consumes the output produced by the device 106. In the illustrated example, the next unit 108 is associated with a display or other downstream system that presents or further processes the inference results produced by the neural network 102 executing on the device 106.

The device 106 of FIG. 1 may be instantiated (e.g., creating an instance of, bring into being for any length of time, materialize, implement, etc.) by programmable circuitry such as a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Also or alternatively, the device 106 of FIG. 1 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 1 may, thus, be instantiated at the same or different times. Some or all of the circuitry of FIG. 1 may be instantiated, for example, in one or more threads executing concurrently on hardware or in series on hardware. Moreover, in some examples, some or all of the circuitry of FIG. 1 may be implemented by microprocessor circuitry executing instructions or FPGA circuitry performing operations to implement one or more virtual machines or containers.

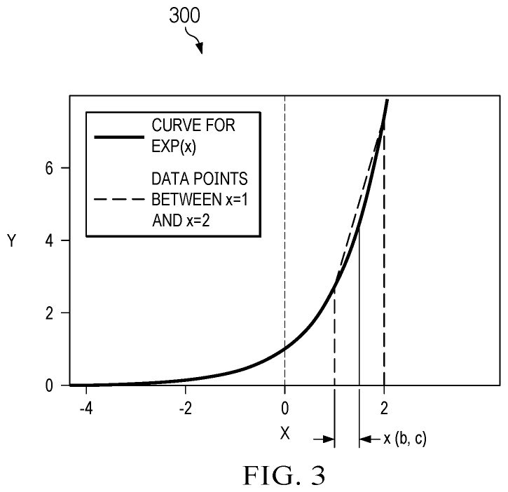

FIG. 2 illustrates an example lookup table apparatus 200 representative of the high-level data flow used to approximate a nonlinear unary function for a given input value. In the illustrated example, the example lookup table apparatus 200 includes an input 202, an index calculation block 204, a lookup table 206, and an output 208.

The example input 202 represents a single numeric value for which an approximation of a nonlinear unary function is to be computed. In the disclosed embodiments, the input 202 is a 16-bit integer value, which may represent a quantized floating-point activation value produced by a preceding layer of the neural network 102 of FIG. 1.

The example index calculation block 204 represents the operation of deriving a lookup table index from the input value 202. In the disclosed embodiments, the index is computed by extracting the most significant 8 bits of the 16-bit input value, which identify the bin within the input domain that contains the input value. The remaining 8 bits of the input value are retained as a fractional component for use in the subsequent interpolation operation.

Because the index is derived from the most significant 8 bits of the 16-bit input value, the index may take any value in the range of 0 to 255, corresponding to 256 distinct bins spanning the input domain. Accordingly, the lookup table 206 contains 256 entries, one for each bin. Each entry stores the pre-computed polynomial interpolation coefficients for the corresponding bin as a 32-bit word, as described herein.

The example lookup table 206 represents the pre-computed data structure in which quantized interpolation coefficients are stored, one entry per input bin. As described herein, each entry in the lookup table 206 stores the polynomial interpolation coefficients for the corresponding bin, computed prior to inference using the pseudo-inverse fitting method and refined through the iterative finetuning process described herein. At inference time, the index derived by the index calculation block 204 is used to retrieve the coefficients for the bin containing the input value 202.

The lookup table 206 may be organized as a flat array of 256 entries, each 32 bits wide, for a total storage requirement of 1024 bytes per function. The 8-bit index derived by the split index and fraction block addresses this array directly, requiring no additional address translation or hash computation. Because the example index is an 8-bit value and the array contains exactly 256 entries, every possible index value maps to a valid entry and no bounds checking is required at runtime. The 4-byte width of each entry allows the entry to be retrieved in a single aligned memory access on processors that support 32-bit load operations. Because the example complete lookup table for a single function requires only 1 KB of storage, lookup tables for multiple functions may be held simultaneously in on-chip shared memory, enabling low-latency coefficient retrieval without off-chip memory accesses during inference. For example, on an example processing system of FIG. 12, an MSMC SRAM serves as the storage location for the precomputed lookup tables, and a navigator subsystem transfers the tables from external LPDDR4 memory into SRAM prior to the start of inference.

The example output 208 represents the coefficients related to the inputs 202, which may be utilized to determine the approximated value of the nonlinear unary function for the given input 202, produced by evaluating the polynomial interpolation expression using the coefficients retrieved from the lookup table 206 and the fractional component of the input value. In the disclosed embodiments, the output 208 is a 16-bit integer value representing the quantized approximation of the target function, which may be passed as input to a subsequent layer of the neural network 102 of FIG. 1.

FIG. 3 illustrates an example graph 300 depicting the linear interpolation of the exponential function exp (x) within a single input bin. The graph 300 illustrates the relationship between the true curve of the target function, the data points within the bin, and the linear approximation line produced by the disclosed method using pre-computed coefficients retrieved from the lookup table 206 of FIG. 2.

The graph 300 depicts the true curve of exp (x) over the illustrated input range, with a representative bin spanning the interval between x=1 and x=2. Within this bin, the disclosed method approximates the true curve using the linear equation y=b*x+c, where the coefficients b and c of the approximation line are retrieved as a pair from the lookup table 206 for the bin corresponding to the index derived from the most significant 8 bits of the input value. The fractional component of the 16-bit input, representing the position of the input value within the bin, is used as the interpolation variable x in the evaluation of the approximation line.

The coefficients b and c stored in the lookup table 206 are computed prior to inference using a pseudo-inverse fitting method. In this method, the coefficient matrix A, comprising the interpolation coefficients to be estimated for each bin, is determined from the matrix of quantized function outputs B and the matrix of input values X within the bin. Specifically, beginning from the linear system:

AX=B

multiplying both sides on the right by X

AXX^{T}=BX^{T}

and solving for A:

A=BX^{T}(XX^{T})⁻¹

where B is the matrix of quantized outputs of the target function evaluated over the input data points in the bin, A is the coefficient matrix to be estimated for each bin, and X is the matrix of input values within the bin. By fitting the coefficients over all input data points within the bin rather than only the endpoints, the pseudo-inverse method produces a more accurate approximation of the target function across the full extent of the bin. Quantized outputs are used in the fitting process to avoid scale shifts at the final stage of the inference calculation.

Because the resulting coefficient values b and c may have different scales, they may be brought to a common scale before addition during inference evaluation. To avoid multiplication and division during this scale adjustment, the scales of the coefficients are rounded to the nearest power of two, allowing scale adjustments to be performed using bit-shift operations. For example, a scale of 1.5 may be adjusted to 2 and a scale of 0.7 may be adjusted to 0.5. Additionally, during coefficient computation, the input values X within each bin are normalized to preserve the numerical precision of the resulting coefficients. As a result, each individual term of the interpolation expression must be adjusted prior to addition during inference, which is accomplished using shifts applied to the individual terms. Following evaluation of the interpolation expression, the top 16 most significant bits of the result are retained as the approximated output value.

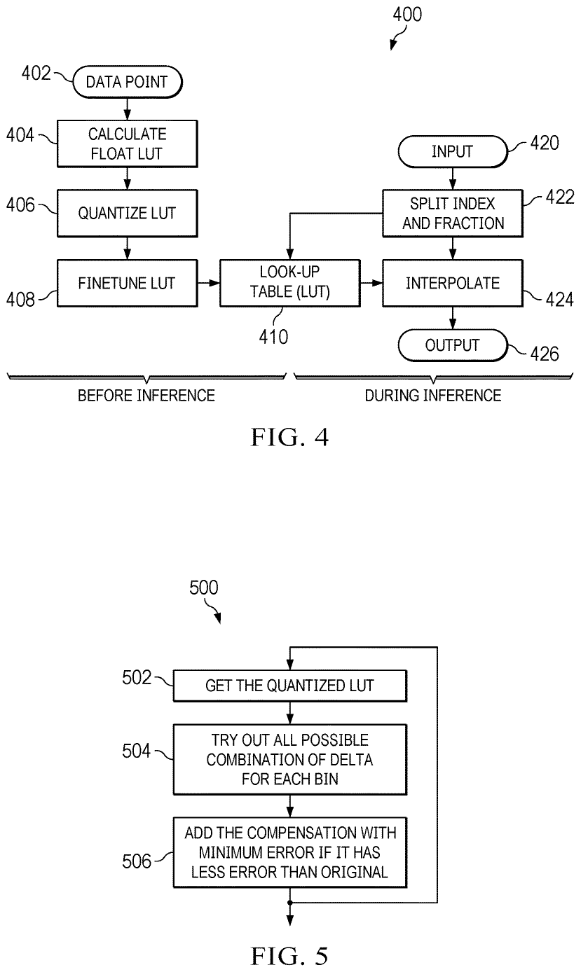

FIG. 4 illustrates an example block diagram 400 depicting the two-phase process by which the disclosed function approximation method generates a lookup table prior to inference and employs that lookup table to produce an approximated output during inference. In the illustrated example, the example block diagram 400 includes a data point 402, a calculate float lookup table block 404, a quantize lookup table block 406, a finetune lookup table block 408, a lookup table 410, an input 420, a split index and fraction block 422, an interpolate block 424, and an output 426. The block diagram 400 is divided into two phases: a before inference phase comprising blocks 402 through 408, and a during inference phase comprising blocks 420 through 426, with the lookup table 410 serving as the interface between the two phases.

The example data point 402 represents the set of input values over which the target nonlinear unary function is evaluated to generate the floating-point lookup table. The data points 402 span the input domain of the target function and are organized into a set of bins, each bin corresponding to one entry in the lookup table 410.

The data points 402 used in the calculate float lookup table block 404 may be sampled uniformly across the input domain of the target function, with an equal number of sample points drawn from within each bin. A uniform sampling strategy ensures that the pseudo-inverse fit for each bin is conditioned on a representative set of input values spanning the full extent of the bin rather than being biased toward either end. The same set of data points used to compute the coefficients for each bin is also used during the iterative finetuning process of FIG. 5 to evaluate the approximation error produced by candidate delta perturbations. Using a consistent set of data points across both the fitting and finetuning stages ensures that the error metric minimized during finetuning is directly comparable to the residual of the original pseudo-inverse fit.

The example calculate float lookup table block 404 receives the data points 402 and computes floating-point interpolation coefficients for each bin using the pseudo-inverse fitting method described herein with respect to FIG. 3. For each bin, the coefficient matrix is estimated from the matrix of function outputs and the matrix of input values within the bin, producing a set of floating-point coefficients that define the polynomial approximation of the target function within that bin.

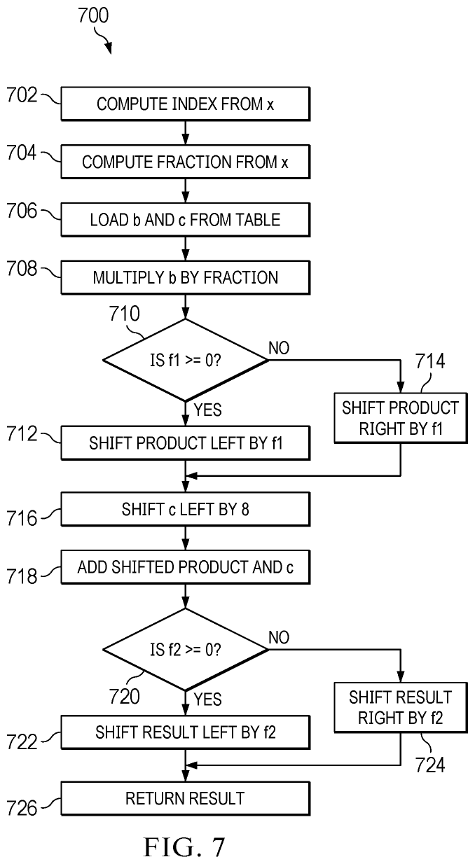

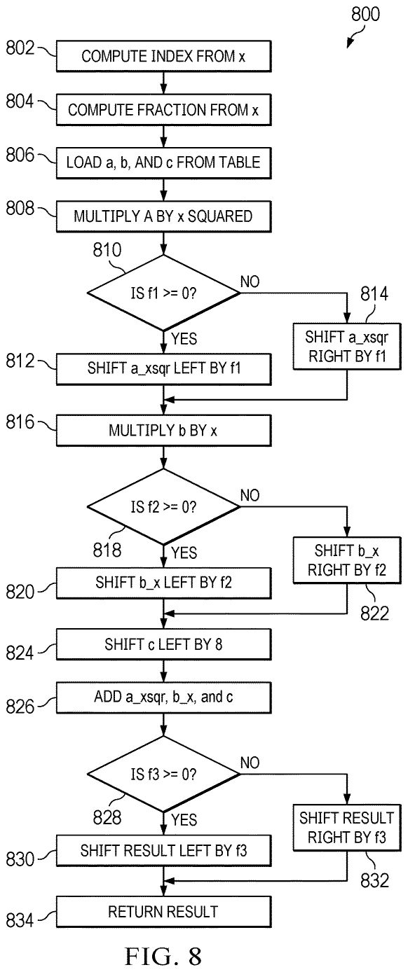

During computation of the interpolation coefficients in the calculate float lookup table block 404, the input values within each bin are normalized before the pseudo-inverse fitting is applied. Specifically, the raw input values within each bin, which span a sub-range of the full 16-bit input domain, are mapped to a normalized range such that the fractional component used in the interpolation expression corresponds to values in the range of 0 to 255, consistent with the 8-bit fractional component extracted from the input during inference. This normalization ensures that the magnitude of the coefficients produced by the pseudo-inverse fit is commensurate with the 8-bit fractional input used at runtime, preventing the coefficients from taking on very large or very small values that would be difficult to represent accurately within the available bit widths. Because the coefficients are computed using normalized inputs but the inference path uses the raw 8-bit fractional component directly, the scale relationship between the coefficient representation and the inference-time inputs is absorbed into the power-of-two scales assigned during quantization and into the shift adjustment factors f1, f2, and f3 applied during the interpolation computation described in conjunction with FIGS. 7 and 8.

The example quantize lookup table block 406 receives the floating-point coefficients produced by the calculate float lookup table block 404 and converts them to integer representations scaled by power-of-two scale factors. The quantization process assigns a separate scale to each coefficient, with each scale rounded to the nearest power of two to allow scale adjustments during inference to be performed using bit-shift operations rather than multiplication or division. The quantized coefficients are packed into 32-bit lookup table entries, with each entry storing the coefficients for one bin.

During the example quantize lookup table block 406, each interpolation coefficient is assigned an independent quantization scale. Because the coefficients for a given bin may span substantially different numerical ranges, assigning a single shared scale to all coefficients would force either the smaller-valued coefficients to lose precision or the larger-valued coefficients to overflow. Accordingly, a separate scale is computed for each coefficient by examining the range of that coefficient's values across all bins and selecting a scale that maps those values into the available integer bit width without overflow. Once each scale is determined, it may be rounded up to the nearest power of two in absolute value. For example, a scale of 1.5 is adjusted to 2 and a scale of 0.7 is adjusted to 0.5. This rounding ensures that scale adjustments utilized during inference can be performed using bit-shift operations rather than multiplication or division. The zero point for each coefficient may be set to zero, meaning the quantization mapping is symmetric about zero. This zero-point constraint may eliminate the need to apply a zero-point offset during inference evaluation, further reducing the arithmetic required at runtime.

The example finetune lookup table block 408 receives the quantized lookup table produced by the quantize lookup table block 406 and applies the iterative finetuning process described further herein with respect to FIG. 5. In the iterative finetuning process, small delta values are applied to each bin's quantized coefficients across all candidate combinations, and the combination yielding the minimum approximation error is retained for each bin. The output of the finetune lookup table block 408 is the finalized lookup table 410, which is stored in on-chip memory prior to the start of inference.

The example input 420 represents a 16-bit integer value for which an approximation of the target nonlinear unary function is to be computed during inference. The input 420 may represent, for example, a quantized activation value produced by a preceding layer of the neural network 102 of FIG. 1.

The example split index and fraction block 422 receives the input 420 and partitions it into two components: an 8-bit index derived from the most significant 8 bits of the input value, and an 8-bit fractional component derived from the least significant 8 bits. The index is used to address the lookup table 410 and retrieve the pre-computed interpolation coefficients for the bin containing the input value. The fractional component is passed to the interpolate block 424 as the interpolation variable.

The example interpolate block 424 receives the fractional component from the split index and fraction block 422 and the interpolation coefficients retrieved from the lookup table 410, and evaluates the polynomial interpolation expression to produce an approximated function value. The individual terms of the interpolation expression are adjusted prior to addition using bit-shift operations to account for the differing power-of-two scales of the coefficients and the normalization applied during coefficient computation. Following evaluation, the top 16 most significant bits of the result are retained.

Although the illustrated example describes linear and quadratic interpolation as two specific embodiments, the disclosed method is not limited to these polynomial orders. The pseudo-inverse fitting framework described herein is applicable to polynomial approximations of any degree, and the lookup table structure may be extended to store additional coefficients to support higher-order interpolation. Higher-order polynomial interpolation may be employed in bins where the target function exhibits high curvature, providing a mechanism to trade increased memory consumption for reduced approximation error as required by a given application.

The example output 426 represents the approximated value of the target nonlinear unary function for the given input 420, produced by the interpolate block 424. The output 426 is a 16-bit integer value representing the quantized approximation of the target function, which may be passed as input to a subsequent layer of the neural network 102 of FIG. 1.

FIG. 5 illustrates an example flowchart 500 representative of example machine-readable instructions or example operations for performing the iterative lookup table finetuning process introduced with respect to the finetune lookup table block 408 of FIG. 4. In the illustrated example, the example flowchart 500 includes a get the quantized lookup table block 502, a delta evaluation block 504, and a compensation selection block 506.

The example get the quantized lookup table block 502 represents the operation of obtaining the quantized lookup table produced by the quantize lookup table block 406 of FIG. 4 as the starting point for the iterative finetuning process. The quantized lookup table at this stage contains, for each bin, a set of interpolation coefficients that have been computed using the pseudo-inverse fitting method and quantized using power-of-two scales as described herein. While the quantized coefficients represent a good approximation of the target function within each bin, the quantization process introduces rounding errors that may be reduced through the finetuning process of FIG. 5.

The example delta evaluation block 504 represents the operation of evaluating candidate perturbations to the quantized coefficients of each bin. For each bin, a small integer delta value in the range of −2 to +2 is applied to each coefficient, and all possible combinations of delta values across the coefficients of the bin are evaluated. For each candidate combination, the approximation error produced by the perturbed coefficients is computed over the input data points within the bin and compared against the error produced by the current coefficients.

The example compensation selection block 506 represents the operation of applying the delta combination that yields the minimum approximation error to the coefficients of each bin, provided that the minimum error achieved by the candidate combination is less than the error of the current coefficients. If no candidate combination produces a lower error than the current coefficients, the coefficients for that bin are left unchanged. The output of the compensation selection block 506 is a refined set of quantized coefficients for each bin, which replaces the previous entries in the lookup table. In the illustrated example, the process of the delta evaluation block 504 and the compensation selection block 506 is repeated for a number of iterations, for example fifty iterations, with each iteration operating on the coefficients produced by the previous iteration. The iterative finetuning process thereby progressively reduces the approximation error of the lookup table entries through successive rounds of localized coefficient perturbation and selection.

The number of iterations performed by the finetuning process is a configurable parameter that may be selected based on the desired balance between approximation accuracy and pre-inference computation time. In the illustrated example, fifty iterations are performed, though fewer or greater numbers of iterations may be used depending on the target function, the acceptable error threshold, and the available pre-inference computation budget.

The delta range of −2 to +2 and the iteration count of fifty represent example values selected to balance approximation accuracy against pre-inference computation time. The delta range may be kept small so that the perturbations applied to each bin's coefficients remain local corrections to the quantization rounding error rather than large adjustments that would undermine the pseudo-inverse fit. Larger delta values would risk introducing systematic error by moving coefficients away from the values that minimize the fitting residual across the full set of data points in the bin. The iteration count controls the depth of the search: each iteration operates on the coefficients produced by the previous iteration, so successive rounds progressively refine the coefficients toward a local minimum of the approximation error. In practice, the error reduction achieved per iteration diminishes as the number of iterations increases. An example of fifty iterations has been found to provide a favorable tradeoff between pre-inference computation time and final approximation accuracy for the functions evaluated. Both parameters may be adjusted for a given target function or application. A tighter error budget may warrant more iterations or a wider delta range, while a constrained pre-inference compute budget may call for fewer iterations.

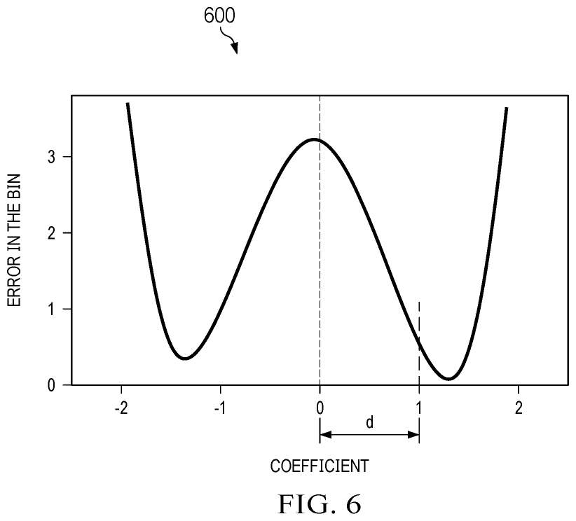

FIG. 6 illustrates an example graph 600 depicting the relationship between the approximation error within a bin and the value of a coefficient delta d applied during the iterative finetuning process of FIG. 5. The graph 600 illustrates how a small perturbation to a quantized lookup table coefficient can reduce the overall approximation error within a bin, providing a visual basis for understanding the effectiveness of the iterative finetuning process.

The horizontal axis of the graph 600 represents the value of the coefficient delta d, spanning a range of candidate perturbation values centered at zero. The vertical axis represents the resulting approximation error in the bin for the corresponding delta value. The curve illustrated in the graph 600 shows the non-monotonic relationship between the delta value and the approximation error, indicating that the error is not minimized at d=0 and that a nonzero delta value may yield a lower approximation error than the unperturbed quantized coefficient.

In the illustrated example, the graph 600 shows that the approximation error reaches a local minimum at a delta value of approximately d=1, corresponding to a coefficient perturbation of positive one applied to the quantized coefficient for that bin. This illustrates the principle underlying the compensation selection block 506 of FIG. 5, in which the delta combination yielding the minimum approximation error is identified and applied to the coefficients of each bin. By searching across all candidate delta combinations in the range of −2 to +2 for each coefficient, the iterative finetuning process is able to identify and apply perturbations of this kind across all bins of the lookup table, progressively reducing the overall approximation error through successive iterations.

Scale adjustment factors f1, f2, and f3 may be derived at lookup table generation time from the power-of-two scales assigned to the coefficients during the quantize lookup table block 406 and from the normalization applied to the input values within each bin during coefficient computation. Because the coefficients are quantized with independent power-of-two scales and the input values are normalized prior to fitting, each term of the interpolation expression carries a different implicit scale that must be brought to a common representation before addition. For linear interpolation, f1 accounts for the scale difference between the b coefficient and the output representation after multiplication by the fractional input, and f2 accounts for the overall scale of the summed result relative to the desired 16-bit output range. For quadratic interpolation, f1 accounts for the scale of the a coefficient after multiplication by the square of the fractional input, f2 accounts for the scale of the b coefficient after multiplication by the fractional input, and f3 accounts for the overall output scale. Each factor is expressed as a signed integer, where a positive value indicates a left shift and a negative value indicates a right shift, allowing both upscaling and downscaling to be represented uniformly. The factors are computed once per function during the pre-inference phase and applied as fixed shift amounts at runtime, so no floating-point arithmetic or division is required during inference to perform scale alignment.

FIG. 7 illustrates an example flowchart 700 representative of example machine-readable instructions or example operations for performing function approximation using lookup-based linear interpolation during inference. The flowchart 700 describes the runtime operations executed by the device 106 of FIG. 1 to evaluate an approximation of a target nonlinear unary function for a given 16-bit input value using the linear interpolation method.

The flowchart 700 begins with the receipt of a 16-bit input value x, corresponding to the input 420 of FIG. 4. The device 106 derives a lookup table index by extracting the most significant 8 bits of the input value x using a right shift operation (block 702). The device 106 may be configurable to perform an 8-bit right shift on the input value x to extract the most significant bits. The device 106 then derives an 8-bit fractional component, representing the position of the input value within the identified bin, by masking the least significant 8 bits of the input value x using a bitwise AND operation (block 704). In some examples, the device 106 is configurable to derive the lookup table index and the fractional component using other numbers of bits from the input value.

Using the index derived in block 702, the device 106 retrieves the pre-computed interpolation coefficients b and c for the corresponding bin from the lookup table 410 of FIG. 4 (block 706). The coefficient b is the quantized slope coefficient and c is the quantized intercept coefficient of the linear approximation equation y=b*x+c for the identified bin, produced by the quantize lookup table block 406 and refined by the finetune lookup table block 408 of FIG. 4.

The device 106 then computes the product of the slope coefficient b and the fractional component derived in block 704, producing an intermediate term b_x representing the scaled linear contribution of the fractional input to the approximated output (block 708).

The device 106 then determines whether the scale adjustment factor f1, which is a pre-determined factor derived from the power-of-two scale assigned to the b coefficient during quantization, is greater than or equal to zero (block 710). If f1 is greater than or equal to zero, the device 106 shifts the product b_x leftward by f1 bits to scale it to the output representation (block 712), which pads b_x with additional least significant bits. If f1 is less than zero, the device 106 instead shifts the product b_x rightward by f1 bits (block 714), effectively clearing the least significant bits of b_x. Both branches of block 710 rejoin at block 716.

The device 106 then left-shifts the intercept coefficient c by 8 bits to align it to the same scale as the scaled b_x term produced in block 712 or block 714 (block 716), which pads c with additional least significant bits. In some examples, the device 106 is configurable to left-shift the intercept coefficient c by another number of bits.

The device 106 sums the scaled b_x term and the scaled c term to produce an intermediate interpolated result y (block 718).

The device 106 then determines whether the scale adjustment factor f2, which is a pre-determined factor derived from the power-of-two scales of the coefficients and the desired output representation, is greater than or equal to zero (block 720). If f2 is greater than or equal to zero, the device 106 shifts the result y leftward by f2 bits (block 722). If f2 is less than zero, the device 106 instead shifts the result y rightward by f2 bits (block 724). Both branches of block 720 rejoin at block 726.

The flowchart 700 concludes with the device 106 returning the result y, with the top 16 most significant bits retained as the approximated output value corresponding to the output 426 of FIG. 4 (block 726). The flowchart 700 can also be expressed as the following pseudo code:

index =x >> 8;
fraction = x & 0x00ff;
b, c ← table[ ] ;
b_x = b × fraction;
if f1 ≥ 0
b_x = b_x << f1;
else
b_x = b_x >> f1;
c = c << 8;
y = b_x + c;
if f2 ≥ 0
y = y << f2;
else
y = y >> f2;
return y;

FIG. 8 illustrates an example flowchart 800 representative of example machine-readable instructions or example operations for performing function approximation using lookup-based quadratic interpolation during inference. The flowchart 800 describes the runtime operations executed by the device 106 of FIG. 1 to evaluate an approximation of a target nonlinear unary function for a given 16-bit input value using the quadratic interpolation method. The flowchart 800 extends the linear interpolation method of FIG. 7 by introducing a quadratic term, enabling a more accurate approximation of target functions with higher curvature within a bin.

The flowchart 800 begins with the receipt of a 16-bit input value x, corresponding to the input 420 of FIG. 4. The device 106 derives a lookup table index by extracting the most significant 8 bits of the input value x using a right shift operation (block 802). The device 106 may be configurable to perform an 8-bit right shift on the input value x to extract the most significant bits. The device 106 then derives an 8-bit fractional component, representing the position of the input value within the identified bin, by masking the least significant 8 bits of the input value x using a bitwise AND operation (block 804). In some examples, the device 106 is configurable to derive the lookup table index and the fractional component using other numbers of bits from the input value.

Using the index derived in block 802, the device 106 retrieves the pre-computed interpolation coefficients a, b, and c for the corresponding bin from the lookup table 410 of FIG. 4 (block 806). The coefficient a is the quantized quadratic coefficient, b is the quantized linear coefficient, and c is the quantized intercept coefficient of the quadratic approximation equation y=a*x2+b*x+c for the identified bin, produced by the quantize lookup table block 406 and refined by the finetune lookup table block 408 of FIG. 4.

The device 106 then computes the product of the quadratic coefficient a and the square of the fractional component derived in block 804, producing an intermediate term a_xsqr representing the quadratic contribution of the fractional input to the approximated output (block 808).

The device 106 then determines whether the scale adjustment factor f1, which is a pre-determined factor derived from the power-of-two scale assigned to the a coefficient during quantization, is greater than or equal to zero (block 810). If f1 is greater than or equal to zero, the device 106 shifts a_xsqr leftward by f1 bits to scale it to the output representation (block 812). If f1 is less than zero, the device 106 instead shifts a_xsqr rightward by f1 bits (block 814). Both branches of block 810 rejoin at block 816.

The device 106 then computes the product of the linear coefficient b and the fractional component derived in block 804, producing an intermediate term b_x representing the linear contribution of the fractional input to the approximated output (block 816).

The device 106 then determines whether the scale adjustment factor f2, which is a pre-determined factor derived from the power-of-two scale assigned to the b coefficient during quantization, is greater than or equal to zero (block 818). If f2 is greater than or equal to zero, the device 106 shifts b_x leftward by f2 bits to scale it to the output representation (block 820). If f2 is less than zero, the device 106 instead shifts b_x rightward by f2 bits (block 822). Both branches of block 818 rejoin at block 824.

The device 106 then left-shifts the intercept coefficient c by 8 bits to align it to the same scale as the scaled a_xsqr and b_x terms (block 824).

The device 106 sums the scaled a_xsqr term, the scaled b_x term, and the scaled c term to produce an intermediate interpolated result y (block 826).

The device 106 then determines whether the scale adjustment factor f3, which is a pre-determined factor derived from the power-of-two scales of the coefficients and the desired output representation, is greater than or equal to zero (block 828). If f3 is greater than or equal to zero, the device 106 shifts the result y leftward by f3 bits (block 830). If f3 is less than zero, the device 106 instead shifts the result y rightward by f3 bits (block 832). Both branches of block 828 rejoin at block 834.

The flowchart 800 concludes with the device 106 returning the result y, with the top 16 most significant bits retained as the approximated output value corresponding to the output 426 of FIG. 4 (block 834).

The flowchart 800 can also be expressed as the following pseudo code:

index = x >> 8;
fraction = x & 0x00ff;
a, b, c ← table[ ] ;
a_xsqr = a × fraction × fraction;
if f1 ≥ 0
a_xsqr = a_xsqr << f1;
else
a_xsqr = a_xsqr >> f1;
b_x = b × fraction;
if f2 ≥ 0
b_x = b_x << f2;
else
b_x = b_x>> f2;
c = c << 8;
y = a__xsqr + b_x + c;
if f3 ≥ 0
y = y << f3;
else
y = y >> f3;
return y ;

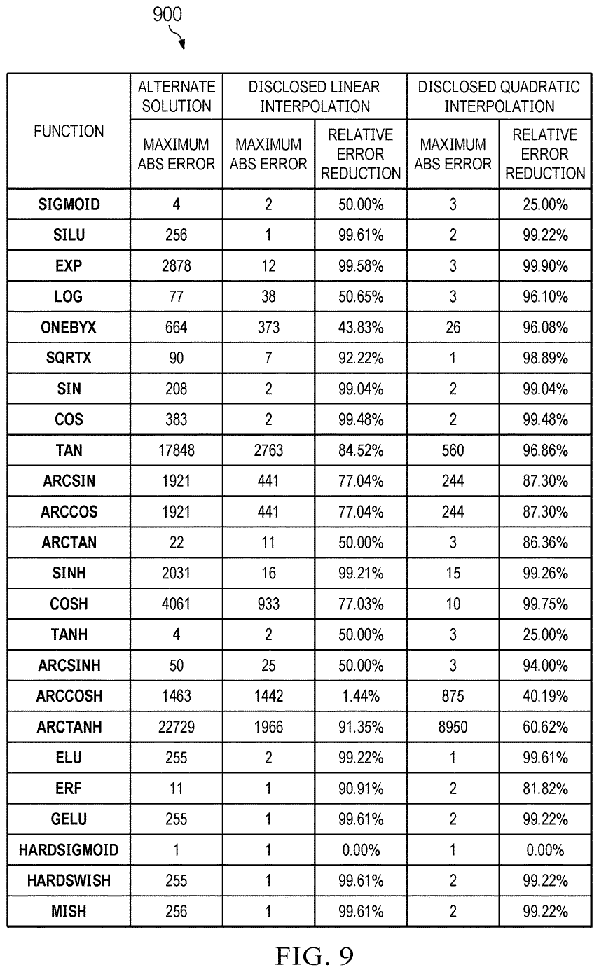

FIG. 9 illustrates an example table 900 comparing the approximation accuracy of the disclosed linear and quadratic interpolation methods against an alternate prior art solution across a range of nonlinear unary functions. The table 900 presents, for each function, the maximum absolute error of the alternate solution and the maximum absolute error of each of the disclosed methods, together with the relative error reduction achieved by each disclosed method relative to the alternate solution. The maximum absolute error values reported in the table 900 are expressed in terms of quantized output values. The results shown in the table 900 demonstrate that the disclosed linear and quadratic interpolation methods achieve substantial reductions in maximum absolute error relative to the alternate solution across the majority of the functions evaluated, including sigmoid, exponential, logarithm, square root, trigonometric, hyperbolic, and neural network activation functions such as SiLU, ELU, GELU, and Mish. In several cases, the disclosed quadratic interpolation method achieves relative error reductions in excess of ninety-nine percent relative to the alternate solution.

Functions that may be evaluated include a first group comprising sigmoid, exponential, logarithm, reciprocal, square root, sine, cosine, tangent, arcsine, arccosine, and arctangent, as well as a second group comprising hyperbolic sine, hyperbolic cosine, hyperbolic tangent, inverse hyperbolic sine, inverse hyperbolic cosine, inverse hyperbolic tangent, exponential linear unit, error function, Gaussian error linear unit, hard sigmoid, hard swish, and Mish. Example results across both groups demonstrate that the disclosed method achieves consistent error reductions relative to the alternate solution across functions with substantially different curvature characteristics, dynamic ranges, and rates of change, including both smooth activation functions commonly used in neural network inference and more rapidly varying trigonometric and hyperbolic functions.

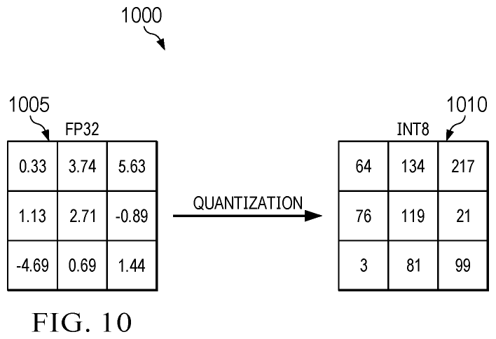

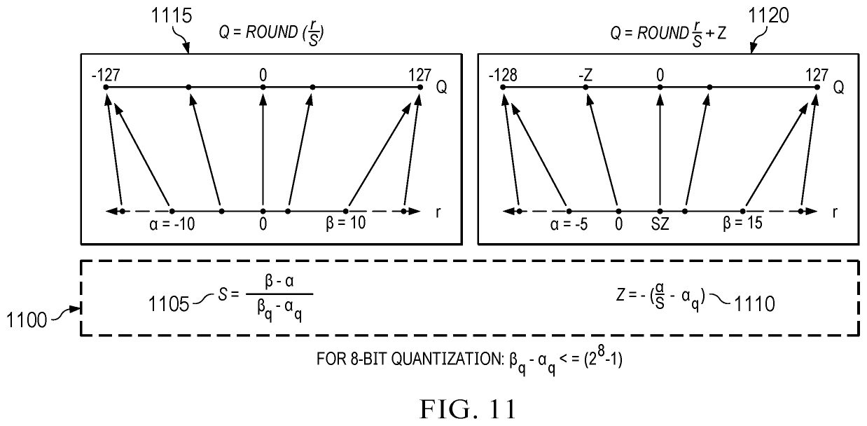

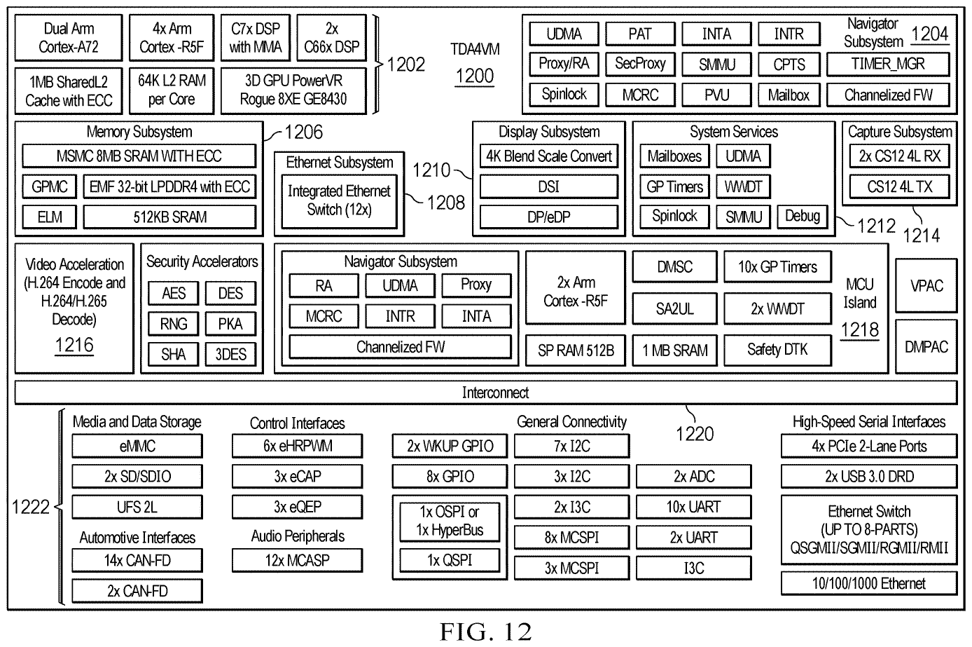

FIG. 10 illustrates an example diagram 1000 depicting the quantization of a matrix of floating-point values to a matrix of integer values. The diagram 1000 shows a source matrix 1005 containing example 32-bit floating-point (FP32) values and a destination matrix 1010 containing the corresponding 8-bit integer (INT8) values produced by applying a quantization operation to the source matrix 1005. The quantization operation maps the floating-point values of the source matrix 1005 to integer values in the destination matrix 1010 by applying a scale factor and zero point as described herein with respect to FIG. 11. The diagram 1000 illustrates the general principle of quantization as applied in the disclosed method, in which floating-point coefficient values computed during the calculate float lookup table block 404 of FIG. 4 are converted to integer representations during the quantize lookup table block 406 of FIG. 4 for storage in the lookup table 410.

FIG. 11 illustrates an example diagram 1100 depicting the quantization parameter relationships used in the disclosed method. The diagram 1100 shows the scale factor S 1105 and zero point Z 1110 that together define the mapping between a floating-point representation and a quantized integer representation.

The scale factor S 1105 is defined as the ratio of the floating-point range, spanning from a minimum value α to a maximum value β, to the corresponding quantized integer range, spanning from a minimum quantized value αq to a maximum quantized value βq, according to the relationship:

$$S = \frac{β - α}{{β}_{q} - {α}_{q}}$$

The zero point Z 1110 is defined as the negation of the ratio of the minimum floating-point value α to the scale factor S, offset by the minimum quantized value αq, according to the relationship:

$$Z = - ( \frac{α}{S} - {α}_{q} )$$

The diagram 1100 illustrates two example quantization schemes: a symmetric scheme 1115 in which the floating-point range is symmetric about zero and the zero point Z is zero, and an asymmetric scheme 1120 in which the floating-point range is not symmetric about zero and a nonzero zero point Z is required to represent the offset. For 8-bit quantization, the constraint βq-αq≤28-1 limits the quantized range to 255 distinct values. In the disclosed method, the quantization parameters are selected such that the scales of the resulting coefficients are powers of two, enabling the scale adjustments performed during inference to be implemented as bit-shift operations as described herein.

FIG. 12 illustrates an example processing system 1200 in which embodiments of the present disclosure may be implemented. The example processing system 1200 includes a processor subsystem 1202, a navigator subsystem 1204, a memory subsystem 1206, an Ethernet subsystem 1208, a display subsystem 1210, system services 1212, a capture subsystem 1214, video acceleration and security accelerators 1216, a microcontroller unit 1218, an interconnect 1220, and peripheral and connectivity subsystems 1222. The example processing system 1200 may be implemented in various applications, including vehicles (e.g., automotive, aircraft, marine, spacecraft, autonomous vehicles, etc.), robotics, networking devices (e.g., modems, routers, and switches), industrial automation (e.g., smart factories), security, surveillance, consumer electronics, medical equipment, motion control, and the like. The techniques of this disclosure may be especially useful for edge AI processors that have relatively limited computation power and memory space.

The example processor subsystem 1202 includes the primary compute resources of the processing system 1200. In some embodiments, the processor subsystem 1202 may include one or more general-purpose processor cores, such as, for example, one or more Arm Cortex-A72 cores or one or more Arm Cortex-R5F cores. The processor subsystem 1202 further includes one or more digital signal processors, such as, for example, a C7x digital signal processor (DSP) with matrix multiply accelerator (MMA) and one or more C66x DSP cores, as well as a graphics processing unit (GPU) such as a 3D GPU. In embodiments of the present disclosure, the C7x DSP and MMA are the primary execution resources for the function approximation operations described herein. Specifically, the C7x DSP executes the lookup table indexing, coefficient retrieval, polynomial interpolation, and bit-shift scale adjustment operations at inference time. The MMA handles matrix multiplication operations for other layers of the neural network, with the C7x DSP handling the unary activation function layers via the disclosed approximation technique.

The example navigator subsystem 1204 provides data movement and queue management infrastructure for the processing system 1200. The navigator subsystem 1204 may include data movement and synchronization components such as, for example, a unified direct memory access controller (UDMA), a ring accelerator (proxy/RA), a secure proxy (SecProxy), a memory cyclic redundancy check controller (MCRC), interrupt aggregators (INTA, INTR), spinlocks, mailboxes, a timer manager (TIMER_MGR), a packet accelerator table (PAT), a system memory management unit (SMMU), a programmable virtualization unit (PVU), a counter and time stamp module (CPTS), and a channelized firewall. In embodiments of the present disclosure, the UDMA and ring accelerator of the navigator subsystem 1204 are employed during the pre-inference phase to transfer precomputed lookup table coefficient data from external memory in the memory subsystem 1206 into on-chip shared memory, as described further herein. This staged data movement enables the C7x DSP to retrieve lookup table entries at low latency during inference without incurring the cost of off-chip memory accesses.

The example memory subsystem 1206 provides program and data storage resources for the processing system 1200. The memory subsystem 1206 may include on-chip and off-chip memory resources such as, for example, a multicore shared memory controller (MSMC) with 8 MB on-chip static random access memory (SRAM) with error correction code (ECC), a 512 KB SRAM, a 32-bit low power double data rate 4 (LPDDR4) external memory interface with ECC, a general purpose memory controller (GPMC), and an error location module (ELM). In embodiments of the present disclosure, the MSMC SRAM serves as the primary storage location for the precomputed lookup table entries used in the function approximation operations described herein. Because the lookup table for a given unary function requires as little as 1 KB of storage, the MSMC SRAM is well suited to hold lookup tables for multiple functions simultaneously, enabling low-latency coefficient retrieval by the C7x DSP during inference. Prior to inference, the LPDDR4 external memory serves as the source from which the navigator subsystem 1204 loads the precomputed coefficient tables into the MSMC SRAM.

The example Ethernet subsystem 1208 provides network connectivity for the processing system 1200. The Ethernet subsystem 1208 may include network interface components such as, for example, an integrated Ethernet switch supporting up to four external ports.

The example display subsystem 1210 provides video output capabilities for the processing system 1200. The display subsystem 1210 may include display interface components such as, for example, a 4K blend and scale converter, a display serial interface (DSI), and a DisplayPort or embedded DisplayPort (DP/eDP) interface.

The example system services 1212 provide shared management and control resources for the processing system 1200. The system services 1212 may include system management components such as, for example, mailboxes, a UDMA, general purpose timers, a watchdog timer (WWDT), spinlocks, an SMMU, and debug infrastructure.

The example capture subsystem 1214 provides image and video input capabilities for the processing system 1200. The capture subsystem 1214 may include capture and vision processing components such as, for example, two camera serial interface 2 (Crib 2) four-lane receivers, a CSI2 four-lane transmitter, a vision processing accelerator (VPAC), and a depth and motion processing accelerator (DMPAC). In embodiments of the present disclosure, the VPAC and DMPAC operate on sensor data as part of the broader neural network inference pipeline within which the function approximation operations described herein are employed.

The example video acceleration and security accelerators 1216 provide dedicated hardware acceleration for video coding and cryptographic operations. The video acceleration portion may include video codec components such as, for example, H.264 encoding and H.264/H.265 decoding engines. The security accelerators may include cryptographic acceleration components such as, for example, advanced encryption standard (AES), secure hash algorithm (SHA), public key accelerator (PKA), random number generator (RNG), data encryption standard (DES), and triple data encryption standard (3DES) engines.

The example microcontroller unit 1218 provides a functionally isolated safety domain within the processing system 1200. The microcontroller unit 1218 may include safety and management components such as, for example, two Arm Cortex-R5F processors with optional lockstep operation, a device management and security controller (DMSC), a security accelerator (SA2UL), a dedicated navigator subsystem comprising a ring accelerator, UDMA, proxy, MCRC, INTR, INTA, and channelized firewall, a 512B scratchpad RAM, 1 MB SRAM, general purpose timers, watchdog timers, and a safety diagnostic toolkit.

The example interconnect 1220 provides the on-chip communication fabric that connects the subsystems of the processing system 1200 to one another, enabling data transfer among the processor subsystem 1202, memory subsystem 1206, navigator subsystem 1204, and all other subsystems described herein.

The example peripheral and connectivity subsystems 1222 provide interfaces between the processing system 1200 and external devices and systems. The peripheral and connectivity subsystems 1222 may include media and data storage interfaces such as embedded multimedia card (eMMC), secure digital input output (SD/SDIO), and universal flash storage (UFS); control interfaces such as enhanced high-resolution pulse width modulator (eHRPWM), enhanced capture module (eCAP), and enhanced quadrature encoder pulse (eQEP); automotive interfaces such as controller area network with flexible data rate (CAN-FD); audio peripherals such as multichannel audio serial port (MCASP); general connectivity interfaces such as general purpose input output (GPIO), octal serial peripheral interface (OSPI), HyperBus, quad serial peripheral interface (QSPI), inter-integrated circuit (I2C), improved inter-integrated circuit (I3C), multichannel serial peripheral interface (MCSPI), analog to digital converter (ADC), and universal asynchronous receiver transmitter (UART); and high-speed serial interfaces such as peripheral component interconnect express (PCIe), universal serial bus 3.0 (USB 3.0), and multi-port Ethernet switch interfaces supporting quad serial gigabit media independent interface (QSGMII), serial gigabit media independent interface (SGMII), reduced gigabit media independent interface (RGMII), and reduced media independent interface (RMII).

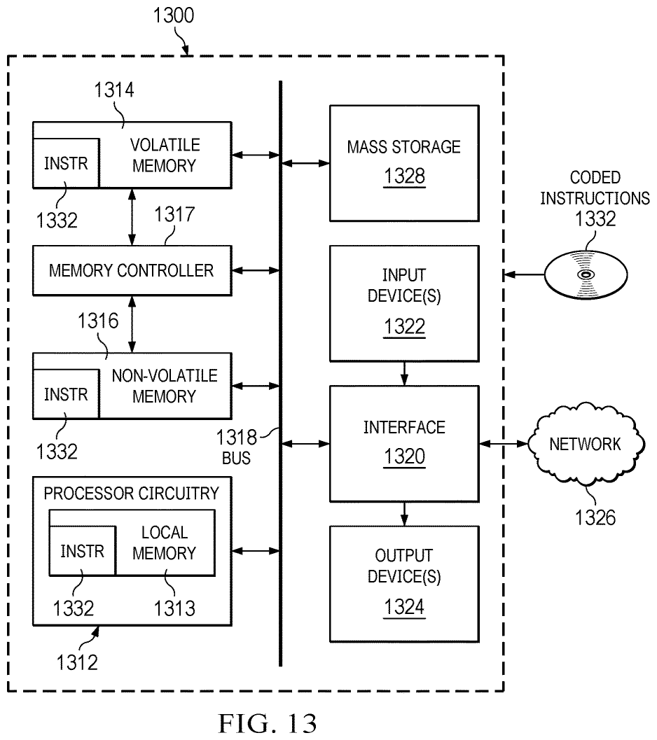

FIG. 13 is a block diagram of an example programmable circuitry platform 1300 structured to one or a combination of execute or instantiate one or more of the example machine-readable instructions or the example operations of FIGS. 4, 5, 7, and/or 8 to implement the device 106 of FIG. 1. The programmable circuitry platform 1300 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1300 of the illustrated example includes programmable circuitry 1312. The programmable circuitry 1312 of the illustrated example is hardware. For example, the programmable circuitry 1312 can be implemented by one or more integrated circuits, logic circuits, FPGAs, microprocessors, CPUs, GPUs, DSPs, or microcontrollers from any desired family or manufacturer. The programmable circuitry 1312 may be implemented by one or more semiconductor based (e.g., silicon based) devices.

The programmable circuitry 1312 of the illustrated example includes a local memory 1313 (e.g., a cache, registers, etc.). The programmable circuitry 1312 of the illustrated example is in communication with main memory 1314, 1316, which includes a volatile memory 1314 and a non-volatile memory 1316, by a bus 1318. The volatile memory 1314 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1316 may be implemented by one or a combination of flash memory or any other desired type of memory device. Access to the main memory 1314, 1316 of the illustrated example is controlled by a memory controller 1317. In some examples, the memory controller 1317 may be implemented by one or more integrated circuits, logic circuits, microcontrollers from any desired family or manufacturer, or any other type of circuitry to manage the flow of data going to and from the main memory 1314, 1316.

The programmable circuitry platform 1300 of the illustrated example also includes interface circuitry 1320. The interface circuitry 1320 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1322 are connected to the interface circuitry 1320. The input device(s) 1322 permit(s) a user (e.g., a human user, a machine user, etc.) to enter one of or a combination of data or commands into the programmable circuitry 1312. The input device(s) 1322 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1324 are also connected to the interface circuitry 1320 of the illustrated example. The output device(s) 1324 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1320 of the illustrated example, thus, includes one of or a combination of a graphics driver card, a graphics driver chip, or graphics processor circuitry such as a GPU.

The interface circuitry 1320 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1326. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1300 of the illustrated example also includes one or more mass storage discs or devices 1328 to store one or more of firmware, software, or data. Examples of such mass storage discs or devices 1328 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1332, which may be implemented by the machine-readable instructions of FIGS. 4, 5, 7, and/or 8, may be stored in one of or a combination of the mass storage device 1328, in the volatile memory 1314, in the non-volatile memory 1316, or on at least one non-transitory computer readable storage medium such as a CD or DVD which may be removable.

While an example manner of implementing the device 106 of FIG. 1 described herein, one or more of the elements, processes, or devices illustrated in FIG. 1 may be combined, divided, re-arranged, omitted, eliminated, or implemented in any other way. Further, the example device 106 of FIG. 1, may be implemented by hardware alone or by hardware in combination with software and firmware. Thus, for example, the example device 106, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example device 106 of FIG. 1 may include one or more elements, processes, or devices in addition to, or instead of, those illustrated in FIG. 1, or may include more than one of any or all of the illustrated elements, processes and devices.

Flowchart(s) representative of example machine-readable instructions, which may be executed by programmable circuitry to at least one of implement or instantiate the device 106 of FIG. 1 or representative of example operations which may be performed by programmable circuitry to at least one of implement or instantiate the device 106 of FIG. 1, are shown in FIGS. 4, 5, 7, and/or 8. The machine-readable instructions may be one or more executable programs or portion(s) of one or more executable programs for execution by programmable circuitry such as the programmable circuitry 1312 shown in the example processor platform 1300. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 4, 5, 7, and/or 8, many other methods of implementing the example device 106 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs and/or one or more FPGAs located in the same package (e.g., the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., or any combination(s) thereof in any of the contexts explained above.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 4, 5, 7, and/or 8 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” may be understood to include (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Modifications are possible in the described embodiments, and other embodiments are possible, within the scope of the claims.

From the foregoing, it will be appreciated that example systems, apparatus, articles of manufacture, and methods have been described that provide high-precision, low-power approximation of nonlinear unary functions using pre-computed, quantized polynomial interpolation coefficients stored in a lookup table. Described systems, apparatus, articles of manufacture, and methods improve the efficiency of using a computing device by eliminating floating-point operations and runtime coefficient estimation from the inference critical path, replacing them with integer arithmetic and bit-shift operations that are executable at substantially lower computational cost on resource-constrained embedded processors. By pre-computing and storing the interpolation coefficients prior to inference, the disclosed method eliminates the need for any coefficient estimation at runtime. Further efficiency may be achieved through the use of power-of-two quantization scales, which allow scale adjustments between coefficient terms to be performed using bit-shift operations in place of multiplication or division, and through the iterative finetuning process, which reduces approximation error without requiring any additional runtime computation. Described systems, apparatus, articles of manufacture, and methods are also directed to one or more improvement(s) in the operation of a machine such as a computer or other electronic, electromechanical, or mechanical device.

Example embodiments of the present disclosure are summarized here. Other embodiments can also be understood from the entirety of the specification and the claims filed herein.

Example methods, apparatus, systems, and articles of manufacture to methods and apparatus for neural network inference acceleration are disclosed herein. Further examples and combinations thereof include the following:

Example 1 includes a device comprising a memory configurable to store a lookup table, and a processing circuit coupled to the memory and configurable to determine a first coefficient and a second coefficient stored in the lookup table at an index corresponding to a first portion of an input value, multiply the first coefficient by a second portion of the input value to determine a scaled contribution term, and add the scaled contribution term and the second coefficient to determine a resulting value.

Example 2 includes the device of example 1, wherein the first coefficient is a slope, wherein the second coefficient is an intercept value, and wherein the scaled contribution term is a contribution of the slope to resulting value.

Example 3 includes the apparatus of any one or more of examples 1-2, wherein the first portion is a most significant bits of the input value, and wherein the second portion is a least significant bits of the input value.

Example 4 includes the apparatus of any one or more of examples 1-3, wherein the processing circuit is configurable to determine the first coefficient, the second coefficient, and a third coefficient stored in the lookup table at the index, wherein the first coefficient, the second coefficient, and the third coefficient are three coefficients of a quadratic equation.

Example 5 includes the apparatus of any one or more of examples 1-4, wherein the lookup table includes 256 entries, and wherein the first coefficient and the second coefficient are one entry of the 256 entries.

Example 6 includes the device of example 5, wherein each entry of the 256 entries is 32 bits long.

Example 7 includes the apparatus of any one or more of examples 1-6, wherein the first portion of the input value is eight bits long.

Example 8 includes the apparatus of any one or more of examples 1-7, wherein the processing circuit is configurable to shift the scaled contribution term by a factor.

Example 9 includes the apparatus of any one or more of examples 1-8, wherein the processing circuit is configurable to shift the second portion of the input value prior to the multiplication.

Example 10 includes the apparatus of any one or more of examples 1-9, wherein the processing circuit is configurable to shift the resulting value prior by a factor to output.

Example 11 includes the apparatus of any one or more of examples 1-10, wherein the resulting value is an interpolated result for a function utilized by a neural network.

Example 12 includes the apparatus of any one or more of examples 1-11, wherein the input value is an integer input value, and wherein the processing circuit is configurable to convert a floating-point input value to the integer input value.

Example 13 includes a non-transitory computer readable medium comprising instructions configurable to cause a processor to determine a first coefficient and a second coefficient stored in a lookup table at an index corresponding to a first portion of an input value, multiply the first coefficient by a second portion of the input value to determine a scaled contribution term, and add the scaled contribution term and the second coefficient to determine a resulting value.

Example 14 includes the non-transitory computer readable medium of example 13, wherein the first coefficient is a slope, wherein the second coefficient is an intercept, and wherein the scaled contribution term is a contribution of the slope to resulting value.

Example 15 includes the apparatus of any one or more of examples 13-14, wherein the first portion is a most significant bits of the input value, and wherein the second portion is a least significant bits of the input value.

Example 16 includes the apparatus of any one or more of examples 13-15, wherein the instructions are configurable to cause the processor to generate the first coefficient, the second coefficient, and a third coefficient that are three coefficients of a quadratic equation.

Example 17 includes the apparatus of any one or more of examples 13-16, wherein the lookup table includes 256 entries, and wherein the first coefficient and the second coefficient are one entry of the 256 entries.

Example 18 includes the non-transitory computer readable medium of example 17, wherein each entry of the 256 entries is 32 bits long.

Example 19 includes the apparatus of any one or more of examples 13-18, wherein the first portion of the input value is eight bits long.

Example 20 includes the apparatus of any one or more of examples 13-19, wherein the instructions are configurable to cause the processor to shift the scaled contribution term by a factor.

Example 21 includes the apparatus of any one or more of examples 13-20, wherein the instructions are configurable to cause the processor to shift the second portion of the input value prior to the multiplication.

Example 22 includes the apparatus of any one or more of examples 13-21, wherein the instructions are configurable to cause the processor to shift the resulting value prior by a factor to output.

Example 23 includes the apparatus of any one or more of examples 13-22, wherein the resulting value is an interpolated result for a function utilized by a neural network.

Example 24 includes the apparatus of any one or more of examples 13-23, wherein the input value is an integer input value, and wherein the instructions are configurable to cause the processor to convert a floating-point input value to the integer input value.

Example 25 includes a method comprising determining a first coefficient and a second coefficient stored in a lookup table at an index corresponding to a first portion of an input value, multiplying the first coefficient by a second portion of the input value to determine a scaled contribution term, and adding the scaled contribution term and the second coefficient to determine a resulting value.

Example 26 includes the method of example 25, wherein the first coefficient is a slope, wherein the second coefficient is an intercept, and wherein the scaled contribution term is a contribution of the slope to resulting value.

Example 27 includes the method of any one or more of examples 25-26, wherein the first portion is a most significant bits of the input value, and wherein the second portion is a least significant bits of the input value.

Example 28 includes the method of any one or more of examples 25-27, further comprising generating the first coefficient, the second coefficient, and a third coefficient that are three coefficients of a quadratic equation.

Example 29 includes the method of any one or more of examples 25-28, wherein the lookup table includes 256 entries, and wherein the first coefficient and the second coefficient are one entry of the 256 entries.

Example 30 includes the method of example 29, wherein each entry of the 256 entries is 32 bits long.

Example 31 includes the method of any one or more of examples 25-30, wherein the first portion of the input value is eight bits long.

Example 32 includes the method of any one or more of examples 25-31, further comprising shifting the scaled contribution term by a factor.

Example 33 includes the method of any one or more of examples 25-32, further comprising shifting the second portion of the input value prior to the multiplication.

Example 34 includes the method of any one or more of examples 25-33, further comprising shifting the resulting value by a factor prior to output.

Example 35 includes the method of any one or more of examples 25-34, wherein the resulting value is an interpolated result for a function utilized by a neural network.

Example 36 includes the method of any one or more of examples 25-35, wherein the input value is an integer input value, and wherein the method further includes converting a floating-point input value to the integer input value.

While this disclosure has been described with reference to illustrative embodiments, this description is not limiting. Various modifications and combinations of the illustrative embodiments, as well as other embodiments, will be apparent to persons skilled in the art upon reference to the description.

1. A device comprising:
a memory configurable to store a lookup table; and
a processing circuit coupled to the memory and configurable to:
determine a first coefficient and a second coefficient stored in the lookup table at an index corresponding to a first portion of an input value;
multiply the first coefficient by a second portion of the input value to determine a scaled contribution term; and
add the scaled contribution term and the second coefficient to determine a resulting value.

2. The device of claim 1,
wherein the first coefficient is a slope,
wherein the second coefficient is an intercept value, and
wherein the scaled contribution term is a contribution of the slope to resulting value.

3. The device of claim 1,
wherein the first portion is a most significant bits of the input value, and
wherein the second portion is a least significant bits of the input value.

4. The device of claim 1,
wherein the processing circuit is configurable to determine the first coefficient, the second coefficient, and a third coefficient stored in the lookup table at the index,
wherein the first coefficient, the second coefficient, and the third coefficient are three coefficients of a quadratic equation.

5. The device of claim 1,
wherein the lookup table includes 256 entries, and
wherein the first coefficient and the second coefficient are one entry of the 256 entries.

6. The device of claim 5, wherein each entry of the 256 entries is 32 bits long.

7. The device of claim 1, wherein the first portion of the input value is eight bits long.

8. The device of claim 1, wherein the processing circuit is configurable to shift the scaled contribution term by a factor.

9. The device of claim 1, wherein the processing circuit is configurable to shift the second portion of the input value prior to the multiplication.

10. The device of claim 1, wherein the processing circuit is configurable to shift the resulting value prior by a factor to output.

11. The device of claim 1, wherein the resulting value is an interpolated result for a function utilized by a neural network.

12. The device of claim 1,
wherein the input value is an integer input value, and
wherein the processing circuit is configurable to convert a floating-point input value to the integer input value.

13. The device of claim 1, wherein the processing circuit is further configurable to generate the lookup table by, for each of a plurality of bins of an input domain, compute a set of floating-point interpolation coefficients using a pseudo-inverse fitting method applied to a matrix of quantized function outputs and a matrix of normalized input values within the bin, and quantizing the set of floating-point interpolation coefficients using a power-of-two scale factor.

14. The device of claim 13, wherein the processing circuit is further configurable to refine the lookup table by, for each bin, applying a plurality of candidate delta values to the quantized interpolation coefficients, evaluating an approximation error for each candidate, and replacing the quantized interpolation coefficients with the candidate that yields a minimum approximation error.

15. The device of claim 14, wherein the processing circuit is configurable to repeat the applying, evaluating, and replacing for a plurality of iterations, each iteration operating on coefficients produced by a preceding iteration.

16. The device of claim 13, wherein the power-of-two scale factor is determined by rounding a computed coefficient scale to a nearest power of two that is higher in absolute value than the computed scale.

17. A non-transitory computer readable medium comprising instructions configurable to cause a processor to:
determine a first coefficient and a second coefficient stored in a lookup table at an index corresponding to a first portion of an input value;
multiply the first coefficient by a second portion of the input value to determine a scaled contribution term; and
add the scaled contribution term and the second coefficient to determine a resulting value.

18-31. (canceled)

32. A method comprising:
determining a first coefficient and a second coefficient stored in a lookup table at an index corresponding to a first portion of an input value;
multiplying the first coefficient by a second portion of the input value to determine a scaled contribution term; and
adding the scaled contribution term and the second coefficient to determine a resulting value.

33. The method of claim 32,
wherein the first coefficient is a slope,
wherein the second coefficient is an intercept, and
wherein the scaled contribution term is a contribution of the slope to resulting value.

34. The method of claim 32,
wherein the first portion is a most significant bits of the input value, and
wherein the second portion is a least significant bits of the input value.

35-46. (canceled)
